(19) United States
(12) Patent Application Publication
(10) Pub. No.: US 2015/0247655 A1
(43) Pub. Date: Sep. 3, 2015

(54) Method of Manufacturing Thermoelectric Device and Thermoelectric Cooling Module and Device Using the Same

(71) Applicants: Jong Bae Shin, Seoul (KR); Sook Hyun Kim, Seoul (KR)

(72) Inventors: Jong Bae Shin, Seoul (KR); Sook Hyun Kim, Seoul (KR)

(21) Appl. No.: 14/367,809

(22) PCT Filed: Dec. 17, 2012
(86) PCT No.: PCT/KR2012/011025

§ 371 Date: Jun. 20, 2014

(30) Foreign Application Priority Data
Dec. 21, 2011 (KR) 10-2011-0138780

(51) Int. Cl. F25B 21/02; H01L 35/30; H01L 35/34

(52) U.S. Cl. CPC F25B 21/02; H01L 35/34; H01L 35/30

(57) ABSTRACT

Provided is a method of manufacturing a thermoelectric device, including: forming a base substrate formed of a main raw material composed of Bi2(SeXTe1-X)3; milling the base substrate; changing a combination composition of any one material selected from Bi, Se and Te in the base substrate; adding and mixing one or more materials selected from Ag, Au, Pt, Cu, Ni, and Al to and with the base substrate and milling them; and forming a thermoelectric semiconductor device by sintering the milled materials.

### TECHNICAL FIELD

The present invention relates to a method of a thermoelectric device capable of implementing high thermoelectric efficiency at room temperature.

### BACKGROUND ART

In general, a thermoelectric device including thermoelectric converting elements which is configured such that a P-type thermoelectric material and an N-type thermoelectric material are bonded between metal electrodes to form a PN bonding pair. When a temperature difference is applied between the PN bonding pair, electric power is produced by a Seeback effect, thereby enabling the thermoelectric device to serve as a power generation device. Further, due to a Peltier effect that one part of the PN boding pair is cooled and another part thereof is heat-radiated, the thermoelectric device serves as a temperature control device.

Here, the Peltier effect refers to such that, as shown in FIG. 1, a p-type material hole and an N-type material electron are moved when applying an external DC voltage thereto to generate and absorb heat on both ends of the materials. The Seeback effect refers to such that, as shown in FIG. 2, the hole and electron are moved to make current to be flowed through the material to generate electric power when receiving external heat.

An active cooling by using the thermoelectric material improves a device thermal stability and further considers as a friendly environment method since there is little noise and vibration and further it does not use a separate condenser and refrigerant and thus accommodates a small amount of space. The application fields for the active cooling using the thermoelectric material refer to as a non-refrigerant refrigerator, air conditioner, various micro-cooling systems, or the like. Specially when the thermoelectric device is attached to various memory devices, the devices are kept in regular and stable temperature while reducing the volume of the devices, thereby improving an performance of the devices.

A factor for measuring a performance of the thermoelectric material refers to a dimensionless performance index ZT (hereinafter referred to as ‘figure of merit’) defined by the following mathematical formula 1.

$$ZT = \frac{S σ T}{k} \qquad [ Formula 1 ]$$

Here, S is seeback coefficient, σ is electrical conductivity, T is absolute temperature and ‘k’ is heat conductivity.

In view of various angles, methods for improving thermoelectric efficiency have been recently reported.

However, the efficiency of the thermoelectric device generally shows high thermoelectric efficiency at 100 to 150° C. Thus, it is problematic that when this thermoelectric device is used to household appliances which can be used at room temperature, the use is limited due to the efficiency.

### DISCLOSURE OF INVENTION

### Technical Problem

The present invention has been made keeping in mind the above problems occurring in the related art. An aspect of the present invention provides a process of manufacturing a thermoelectric device, and a thermoelectric module using the thermoelectric device, the thermoelectric device being produced by adding a metal material to Bi₂(Se_{X}Te_{1-X})₃ at the same time as applying a variation to a rate of one or more elements of Bi, Se, Te which are main elements of Bi₂(Se_{X}Te_{1-X})₃ so that thermoelectric device can show a high thermoelectric performance at a room temperature area of 25 to 50° C. thereby enabling the thermoelectric device to be used in the home.

### Solution to Problem

According to an aspect of the present invention, there is provided a method of manufacturing a thermoelectric device, including: forming a base substrate with a main raw material composed of Bi₂(Se_{X}Te_{1-X})₃; milling the base substrate; changing a combination composition of any one material selected from Bi, Se, and Te in the base substrate; mixing and milling one or more materials selected from Ag, Au, Pt, Cu, Ni and Al with the base substrate; and forming a thermoelectric semiconductor device by sintering the milled materials.

### Advantageous Effects of Invention

According to the present invention, the thermoelectric device is produced by adding a metal material to Bi₂(Se_{X}Te_{1-X})₃ at the same time as applying a variation to a rate of one or more elements of Bi, Se, Te which are main elements of Bi₂(Se_{X}Te_{1-X})₃, and thus it is advantageous that thermoelectric device can show a high thermoelectric performance at a room temperature area of 25 to 50° C.

### BRIEF DESCRIPTION OF DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIG. 1 and FIG. 2 are conceptual views illustrating a structure of a conventional thermoelectric module.

FIG. 3 is a process view illustrating a manufacturing process of a thermoelectric device according to the present invention.

FIG. 4 and FIG. 5 are a table and a graph of test results illustrating efficiency of the thermoelectric device according the present invention.

FIG. 6 is a conceptual view illustrating a structure of a unit thermoelectric module according to the present invention.

FIG. 7 is a conceptual view illustrating a configuration of a thermoelectric cooling module according to the present invention including the plurality of unit thermoelectric modules.

### BEST MODE FOR CARRYING OUT THE INVENTION

Exemplary embodiments according to the present invention will now be described more fully hereinafter with reference to the accompanying drawings. In the explanation with reference to the accompanying drawings, regardless of reference numerals of the drawings, like numbers refer to like elements through the specification, and repeated explanation thereon is omitted. Terms such as a first term and a second term may be used for explaining various constitutive elements, but the constitutive elements should not be limited to these terms. These terms is used only for the purpose for distinguishing a constitutive element from other constitutive element.

A process of manufacturing a thermoelectric device according to the present invention includes: forming a base substrate with a main raw material composed of Bi₂ (Se_{X}Te_{1-X})₃; milling the base substrate changing a combination composition of any one material selected from Bi, Se, and Te in the base substrate; mixing and milling one or more materials selected from Ag, Au, Pt, Cu, Ni and Al with the base substrate; and forming a thermoelectric semiconductor device by sintering the milled materials.

The aforesaid process will be specifically reviewed with reference to FIG. 3.

In the production of the thermoelectric device according to the present invention, as shown in step S1, the base substrate is first formed in an ingot shape with a main raw material composed of a BiTe-based material including Sb, Se, B, Ga, Te, Bi and In. According to a preferred exemplary embodiment of the present invention, the base material in the ingot shape obtained through heat treatment of the main raw material composed of Bi₂(Se_{X}Te_{1-X})₃ is used.

Then, a process of milling the base substrate in the ingot shape is performed. In this case, before changing a combination composition of any one material selected from Bi, Se and Te in the base substrate, it would be preferable that a process of adding or removing any one, or two or more materials of Bi, Se and Te up to a ratio corresponding to 0.01 wt % to 1.0 wt % of a total weight of the base substrate is performed.

Specifically, in this case, to maximize the efficiency of the thermoelectric semiconductor device which is formed of a P-type device or an N-type device, a process of adding and milling any one, or two or more elements of Bi, Se and Te up to a ratio corresponding to 0.01 wt % to 1.0 wt % of a total weight of the main raw material composed of Bi₂(Se_{X}Te_{1-X})₃ is performed, and the added materials have an effect on a unit element as a mixture, thereby improving the efficiency of the unit element.

In the process of step S2, a process of adding and milling one metal, or two or more metals selected from Ag, Au, Pt, Cu, Ni and Al up to a ratio corresponding to 0.01 wt % to 1.0 wt % of a total weight of the base substrate may be performed. The addition of the metal dopant materials shows an effect that a temperature showing a maximum performance value of the thermoelectric device is decreased from a range of 100° C. to 150° C. to a range of 20° C. to 50° C.

Then, in the process of step S3, a process of sintering the milled materials using any one process of sintering processes including an atmospheric pressure sintering method, a press sintering method, a hot isostatic pressing (HIP) method, a spark plasma sintering (SPS) method, a microwave sintering method, an electrically assisted sintering method, and then the sintered materials are cut (S4), and thus the thermoelectric semiconductor device is produced (S5).

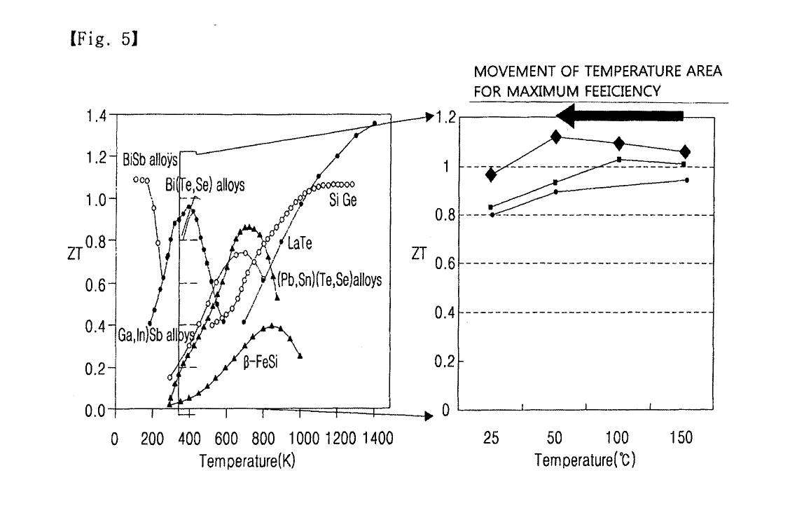

The variation in efficiency of the thermoelectric device produced by the aforesaid process will be reviewed with reference to FIG. 4 and FIG. 5.

Referring to FIG. 4 and FIG. 5, FIG. 4 is a test result showing the variation in efficiency of the thermoelectric device during the aforesaid process according to the present invention. FIG. 5 is a graph resulting from this.

It can be confirmed that a ZT level of a standard sample formed of the main raw material composed of Bi₂(Se_{X}Te_{1-X})₃ generally shows maximum efficiency at 150° C. In addition to this, in a case where the process of adding or removing any one, or two or more materials of Bi, Se and Te up to the ratio corresponding to 0.01 wt % to 1.0 wt % of the total weight of the base substrate is performed, namely, in a test group to which ‘a variation in basic composition’ is applied, a temperature which the ZT level show maximum efficiency is decreased to 100° C. However, it is still problematic that it is difficult to apply the thermoelectric device to a home device used at a room temperature of 100° C.

Here, in a case where the process of adding or removing any one, or two or more materials of Bi, Se and Te, and the process of adding (i.e. the addition of dopant) any one metal, or two or more metals selected from Ag, Au, Pt, Cu, Ni and Al up to the ratio corresponding to 0.01 wt % to 1.0 wt % of the total weight of the base substrate are performed together, as illustrated in FIG. 5, it can be confirmed that a temperature area showing the maximum efficiency is decreased from about 100° C. to a range of 20° C. to 50° C. Thus, in a case where the aforesaid metal dopant materials are added, in the temperature area of 20° C. to 50° C. electrical conductivity of an inner part of thermoelectric materials is improved. As a result, in the low temperature area of the room temperature, high thermoelectric performance is realized.

In the process of adding (the addition of dopant) any one metal, or two or more metals selected from Ag, Au, Pt, Cu, Ni and Al up to the ratio corresponding to 0.01 wt % to 1.0 wt % of the total weight of the base substrate, a ratio of the added metal dopant materials is 0.01 wt % to 1.0 wt % of the total weight of the base substrate.

For example, in a case where two materials of the metal dopant materials are selected, a combination ratio of a first ingredient A and a second ingredient B selected from Ag, Au, Pt, Cu, Ni and Al may be embodied as A(1-X) wt % and B(X) wt %. For example, when the selected materials are Ag and Au, a content of the materials may be combined as Ag (0.01 wt %)+Au (0.01 wt % to 0.99wt %) or Ag (0.01 wt % to 0.99 wt %)+Au (0.01 wt %). (wherein, X represents a rational number of positive of more than 0.01.)

Thus, the thermoelectric device according to the present invention shows maximum efficiency which may be used in a room temperature area. The thermoelectric device may be used in all of general products used at room temperature. That is, it is applicable to a wine refrigerator, a Kimchi refrigerator, a medicated water electrolysis apparatus, a water purifier, a dryer, a dehumidifier, a car seat, a vehicle-mounted refrigerator, a cold cup holder, a blood storage apparatus and the like.

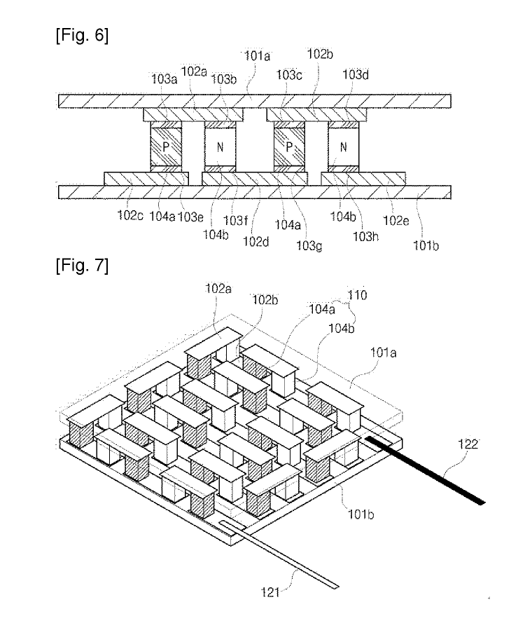

FIG. 6 is a conceptual view illustrating a structure of a thermoelectric module to which the thermoelectric device according to the present invention is applied. FIG. 7 is a conceptual view illustrating one exemplary embodiment of a thermoelectric cooling module according the present invention including the plurality of thermoelectric modules.

Referring to FIG. 6 and FIG. 7, a thermoelectric module including the thermoelectric device according to the present invention includes at least one or more unit thermoelectric modules including a P-type semiconductor device or an N-type semiconductor device, one ends thereof being electrically connected by electrodes, wherein the P-type semiconductor device or the N-type semiconductor device may use the thermoelectric device produced by the manufacturing method according to the present invention and formed using a material in which any one or more materials selected from Ag, Au, Pt, Cu, Ni and Al is added to the main raw material composed of Bi₂(Se_{X}Te_{1-X})₃.

Specifically, as illustrated in FIG. 6, the thermoelectric module may be configured such that metal electrodes 102a, 102b, 102c, 102d, 102e such as a copper plate are arranged between a first substrate 101a and a second substrate 101b, and thereon the P-type semiconductor 104a and the N-type semiconductor 104b are alternately formed or only any one of the semiconductors is formed. As a result, one ends of the P-type semiconductor 104a and the N-type semiconductor 104b are electrically connected to each other through the metal electrodes 102a, 102b, 102c, 102d, 102e. Furthermore, diffusion barrier layers 103a, 103b, 103c, 103d, 103e, 103f, 103g, 103h for the prevention of diffusion may be formed between the semiconductors and the electrodes. In this structure, when the P-type semiconductor 104 and the N-type semiconductor 104b are formed, the thermoelectric device, which is produced by the process of adding any one, or two or more elements selected from Bi, Se and Te corresponding to the range of 0.01 wt % to 1.0 wt % of the total weight of the main raw material composed of Bi₂(Se_{X}Te_{1-X})₃, and the process of adding, milling and sintering any one metal, or two or more metals selected from Ag, Au, Pt, Cu, Ni and Al up to the ratio corresponding to 0.01 wt % to 1.0 wt % of the total weight of the base substrate, may be used as described above.

A structure in which the thermoelectric modules formed by the unit thermoelectric modules in FIG. 6 is formed in plural number will be reviewed with reference to FIG. 7.

The P-type semiconductor 104a and the N-type semiconductor 104b are connected to the metal electrodes 102a, 102b, and generate a Peltier effect due to circuit lines 121, 122 which supply currents to the semiconductor device through the electrodes, and in which the structure is formed in plural number. The unit thermoelectric module may be freely designed in 8 to 1024 pairs. In this case, a size of the semiconductor device may variously range from 0.1 mm to 1 m.

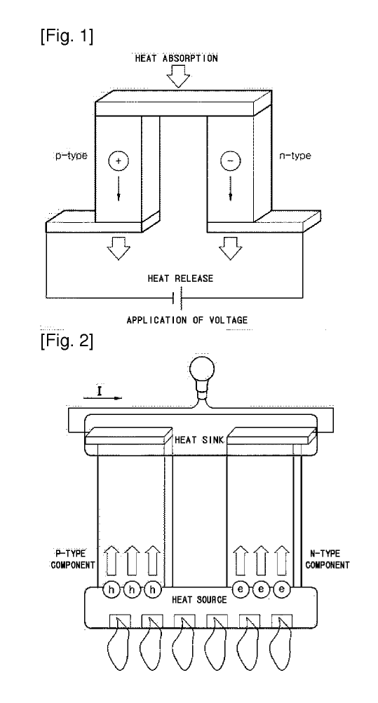

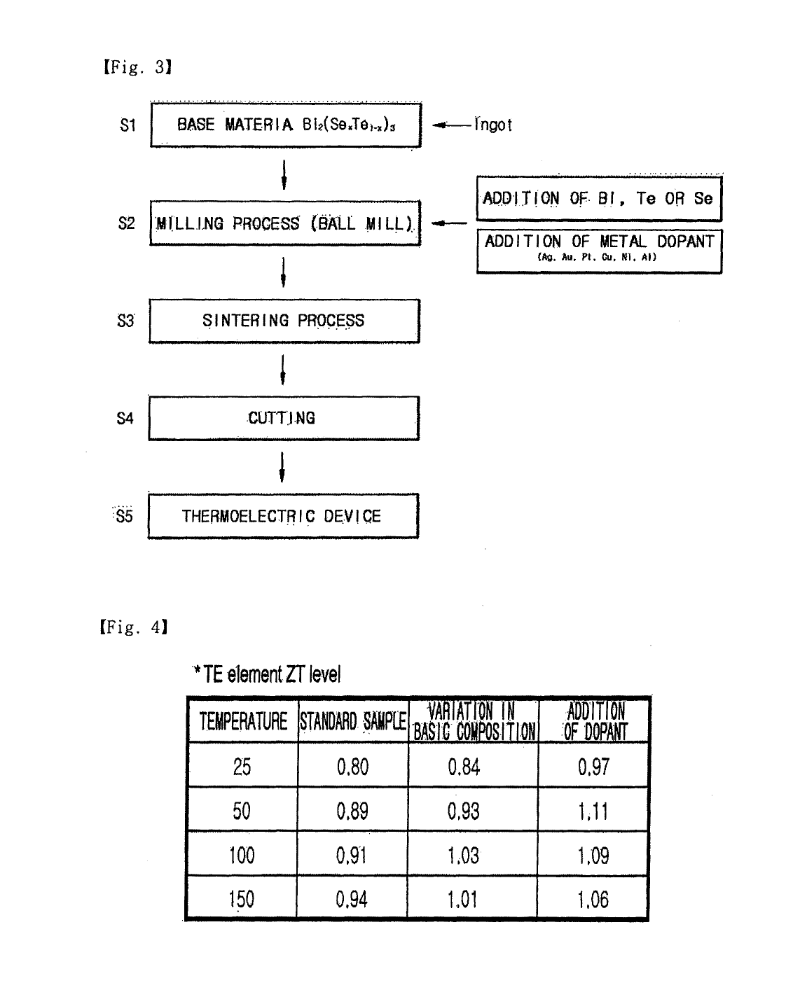

Moreover, a first substrate 101a and a second substrate 101b which are formed on the semiconductor device in FIG. 1 may be formed of any one of Fe, Al, Ni, Mg, Ti, Cu, Ag, Au, Pt, Si, C and Pb. The metal electrodes 102a, 102b, 102c, 102d, 102e which come into contact with the substrates may be formed of at least one metal selected from a group including Cu, Ag, Ni, Al, Au, Cr, Ru, Re, Pb, Cr, Sn, In, Zn or an alloy including these metals. Furthermore, the diffusion barrier layers 103a, 103b, 103c, 103d, 103e, 103f, 103g, 103h may be formed of at least one metal selected the group including Cu, Ag, Ni, Al, Au, Cr, Ru, Re, Pb, Cr, Sn, In and Zn, or an alloy including these metals.

As previously described, in the detailed description of the invention, having described the detailed exemplary embodiments of the invention, it should be apparent that modifications and variations can be made by persons skilled without deviating from the spirit or scope of the invention. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims and their equivalents.

### INDUSTRIAL APPLICABILITY

The thermoelectric device according to the present invention is advantageous that it can show maximum efficiency at a low temperature area by providing a variation in composition, and thus it can be used at a lower temperature area (i.e. 25° C. to 50° C. than the temperature area showing the efficiency of the conventional thermoelectric device, namely, 100° C. to 150° C. In the future, the temperature area showing high efficiency can be expressed as a lower temperature area.

Accordingly, the thermoelectric device may be used in all of general products used at room temperature, and may be also applied to the wine refrigerator, the Kimchi refrigerator, the ion water purifier, a water purifier, the dryer, the dehumidifier, the car seat, the vehicle-mounted refrigerator, the cold cup holder, a blood storage apparatus and the like.

1. A method of manufacturing a thermoelectric device, comprising:
changing a combination composition of any one material selected from Bi, Se and Te of a main raw material composed of Bi₂(Se_{X}Te_{1-X})₃;
adding and mixing one or more materials selected from Ag, Au, Pt, Cu, Ni, and Al to and with the main raw material in which the combination composition is changed; and
forming a thermoelectric semiconductor device by sintering the main raw material and the added and mixed materials.

2. The method of claim 1, wherein the changing of the combination composition of any one material selected from Bi, Se and Te of the main raw material is performed by forming a base substrate formed of the main raw material composed of Bi₂(Se_{X}Te_{1-X})₃and adding any one, or two or more materials of Bi, Se and Te or removing a fixed amount thereof by milling the base substrate.

3. The method of claim 2, wherein the sintering of the main raw material and the added and mixed materials is performed by sintering the main raw material and the added and the mixed materials after milling them again.

4. The method of claim 3, wherein the forming of the thermoelectric semiconductor device by sintering the milled materials uses any one of sintering processes including an atmospheric pressure sintering method, a press sintering method, a hot isostatic pressing (HIP) method, a spark plasma sintering (SPS) method, a microwave sintering method and an electrically assisted sintering method.

5. The method of claim 2, wherein the changing of the combination composition of any one material selected from Bi, Se and Te in the base substrate corresponds to a process of adding or removing any one material, or two or materials of Bi, Se and Te up to a ratio corresponding to 0.01 wt % to 1.0 wt % of a total weight of the base substrate.

6. The method of claim 2, wherein the adding and mixing of one or more materials selected from Ag, Au, Pt, Cu, Ni and Al correspond to a process of adding any one metal, or two or more metals selected from Ag, Au, Pt, Cu, Ni and Al up to the ratio corresponding to 0.01 wt % to 1.0 wt % of the total weight of the base substrate.

7. The method of claim 2, wherein the adding and mixing of one or more materials selected from Ag, Au, Pt, Cu, Ni and Al are performed by implementing a combination ratio a first ingredient (A) and a second ingredient(B) selected from Ag, Au, Pt, Cu, Ni and Al as A (1-X) wt % and B (X) wt %. (wherein X represents a rational number of position of more than 0.01.)

8. A thermoelectric cooling module comprising:
at least one or more unit thermoelectric modules including a P-type semiconductor device or an N-type semiconductor device disposed to be spaced apart from each other; and an electrode for electrically connecting one ends of the P-type semiconductor device and the N-type semiconductor device, wherein the P-type semiconductor device or the N-type semiconductor device is formed of a material to which one or more materials selected from Ag, Au, Pt, Cu, Ni and Al are added to a main raw material.

9. The thermoelectric cooling module of claim 8, further comprising a first substrate and a second substrate which are opposed to each other so as to be disposed in an inner part of the semiconductor device.

10. The thermoelectric cooling module of claim 9, wherein the electrode is patterned on a surface of an inner side of the first substrate and the second substrate.

11. The thermoelectric cooling module of claim 9, wherein the thermoelectric modules are formed with only any one of the P-type semiconductor device and the N-type semiconductor device.

12. The thermoelectric cooling module of claim 9, wherein the thermoelectric modules are formed in a structure in which the P-type semiconductor device and the N-type semiconductor device are alternately disposed.

13. The thermoelectric cooling module of claim 9, wherein the first substrate and the second substrate are formed of any one of Fe, Al, Ni, Mg, Ti, Cu, Ag, Au, Pt, Si, C and Pb.

14. The thermoelectric cooling module of claim 8, wherein the electrode is formed of at least one metal selected from a group including Cu, Ag, Ni, Al, Au, Cr, Ru, Re, Pb, Cr, Sn, In and Zn or an alloy including these metals.

15. The thermoelectric cooling module of claim 9, further comprising a diffusion barrier layer which is disposed between the electrode formed on a surface of an inner side of the substrates and one end of the semiconductor devices and prevents metals from being diffused.

16. The thermoelectric cooling module of claim 8, wherein the diffusion barrier layer is formed of at least one metal selected from a group including Cu, Ag, Ni, Al, Au, Cr, Ru, Re, Pb, Cr, Sn, In and Zn or an alloy including these metals.

17. A cooling device, comprising: the thermoelectric module according to claim 8.
